(19) United States
(12) Patent Application Publication
(10) Pub. No.: US 2022/0352448 A1
(43) Pub. Date: Nov. 3, 2022

(54) LIGHT EMITTING MODULE AND DISPLAY DEVICE

(71) Applicant: Optoma Corporation, New Taipei City (TW)

(72) Inventors: Cheng-Chien Ou, Hsin-Chu (TW); Chia Yu Li, Hsin-Chu (TW); Shih-Hung Hsu, Hsin-Chu (TW); Kuo-Yuan Hung, Hsin-Chu (TW)

(73) Assignee: Optoma Corporation, New Taipei City (TW)

(21) Appl. No.: 17/717,143

(22) Filed: Apr. 11, 2022

(30) Foreign Application Priority Data
Apr. 29, 2021 (CN) 202110471736.7

(51) Int. Cl. H01L 33/62; H01L 25/075; H01L 33/48

(52) U.S. Cl. CPC H01L 33/62; H01L 25/0753; H01L 33/486

(57) ABSTRACT

Provided is a light emitting module, including multiple light emitting units and a multi-layer board. Each light emitting unit includes multiple light emitting elements and side connectors. Each light emitting element includes first and second ends. The light emitting units are disposed on the multi-layer board. The first and second ends of each light emitting element are connected to the side connectors through multiple through holes of the multi-layer board. The first ends of the light emitting elements of first and second light emitting units are electrically connected to each other. The first ends of the light emitting elements of third and fourth light emitting units are electrically connected to each other. The display device using the light emitting module of the disclosure may conduct the adjacent light emitting units to each other through the side connectors, increasing repair possibility and reducing the scrap uncontrolled rate of the display device.

### CROSS-REFERENCE TO RELATED APPLICATION

This application claims the priority benefit of China application serial no. 202110471736.7, filed on Apr. 29, 2021. The entirety of the above-mentioned patent application is hereby incorporated by reference herein and made a part of this specification.

### BACKGROUND

### Technical Field

The disclosure relates to an optical module and an optical device, and more particularly to a light emitting module and a display device having the light emitting module.

### Description of Related Art

In an era of rapid technological development, the display device has gradually become an indispensable part of life. Generally speaking, in a light emitting diode display screen, pins of light emitting diodes are assembled and soldered to a printed circuit board (PCB) by surface-mount technology (SMT). However, the current design of the light emitting diode display screen is unable to solve the problem that the light emitting diodes or the pads on the printed circuit board fall off and are damaged when the light emitting diode display screen suffers an impact. When the light emitting diode display screen suffers an impact, it can only be repaired passively by disassembling the printed circuit board and the light emitting diodes or scrapping the damaged printed circuit board.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a light emitting module, which may increase repair possibility.

The disclosure provides a display device, including the light emitting module, which may reduce the scrap uncontrolled rate.

Other objectives and advantages of the disclosure may be further understood from the technical features disclosed herein.

In order to achieve one or a part or all of the above or other objectives, an embodiment of the disclosure provides a light emitting module, including multiple light emitting units and a multi-layer board. Each of the light emitting units includes multiple light emitting elements and multiple side connectors. Each of the light emitting elements includes a first end and a second end. The light emitting units are disposed on the multi-layer board. The first end and the second end of each of the light emitting elements are connected to the side connectors through multiple through holes of the multi-layer board. The first ends of the light emitting elements of a first light emitting unit and a second light emitting unit among the light emitting units are electrically connected to each other. The first ends of the light emitting elements of a third light emitting unit and a fourth light emitting unit among the light emitting units are electrically connected to each other.

In order to achieve one or a part or all of the above or other objectives, an embodiment of the disclosure provides a display device, including a driving substrate and multiple light emitting modules. The light emitting modules are disposed on the driving substrate and are electrically connected to the driving substrate. Each of the light emitting modules includes multiple light emitting units and a multi-layer board. Each of the light emitting units includes multiple light emitting elements and multiple side connectors. Each of the light emitting elements includes a first end and a second end. The light emitting units are disposed on the multi-layer board. The first end and the second end of the light emitting elements are connected to the side connectors through multiple through holes of the multi-layer board. The first ends of the light emitting elements of a first light emitting unit and a second light emitting unit among the light emitting units are electrically connected to each other. The first ends of the light emitting elements of a third light emitting unit and a fourth light emitting unit among the light emitting units are electrically connected to each other. The adjacent light emitting units are conducted to each other through the side connectors.

Based on the above, the embodiments of the disclosure have at least one of the following advantages or effects. In the design of the light emitting module of the disclosure, the light emitting units are disposed on the multi-layer board and include multiple light emitting elements and multiple side connectors. The first end and the second end of the light emitting elements are connected to the side connectors. In addition, the first ends of the light emitting elements of the first light emitting unit and the second light emitting unit among the light emitting units are electrically connected to each other, the first ends of the light emitting elements of the third light emitting unit and the fourth light emitting unit among the light emitting units are electrically connected to each other. In this way, the light emitting module of the disclosure has a three-path parallel circuit design, which may improve the repair possibility of the light emitting module of the disclosure. In addition, the display device using the light emitting module of the disclosure may allow the adjacent light emitting units to be conducted to each other through the side connectors. Therefore, when multiple light emitting units in the display device are subjected to a strong impact making some of the light emitting units unable to be electrically connected to the driving substrate, the repair possibility may be increased and the scrap uncontrolled rate of the display device may be reduced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a light emitting module of a display device of an embodiment according to the disclosure.

FIG. 2 is a schematic view of a driving chip and a driving substrate of the display device in FIG. 1.

FIG. 3 is a partially enlarged schematic view of the light emitting module of the display device in FIG. 1.

FIG. 4 is a perspective schematic view of a multi-layer board of the light emitting module of the display device in FIG. 1.

FIG. 5A is a circuit schematic view of the light emitting module in the display device in FIG. 1.

FIG. 5B is a circuit schematic view of a light emitting module in a display device of another embodiment of the disclosure.

FIG. 6 is a schematic bottom view of the light emitting module of the display device in FIG. 1.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

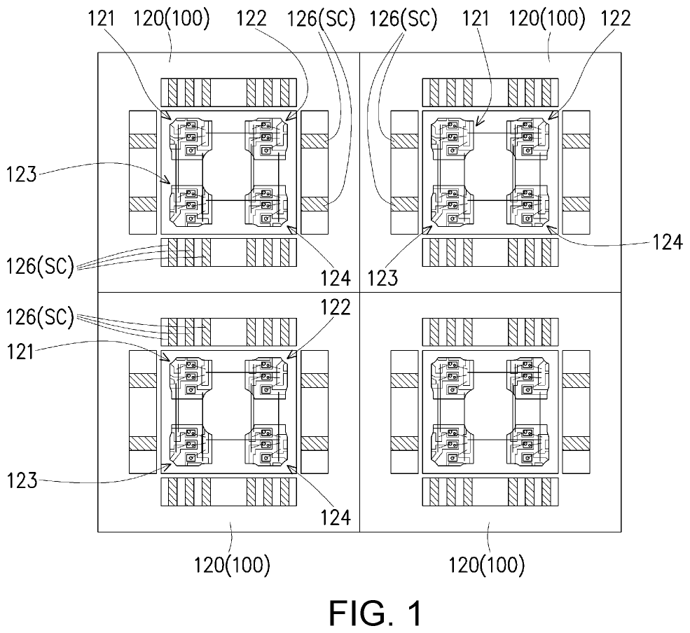

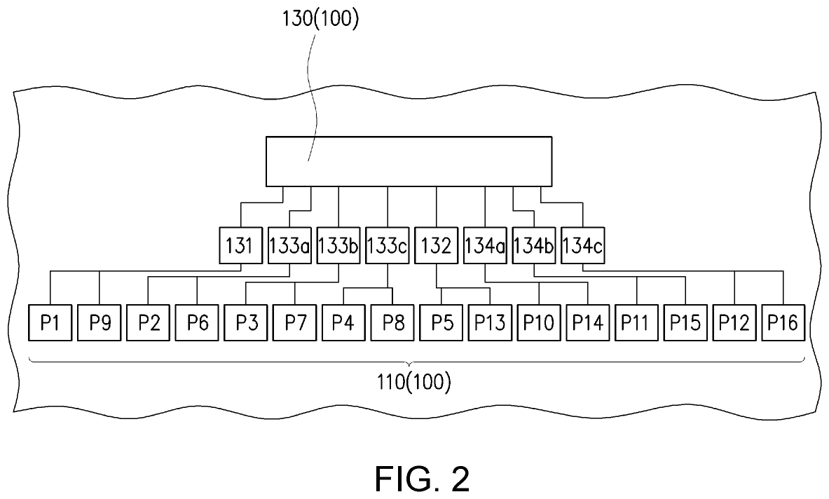

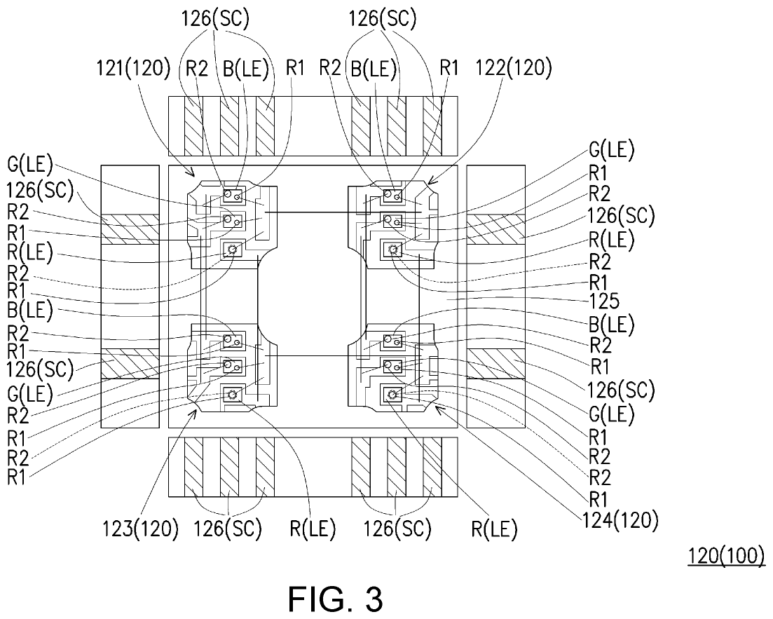

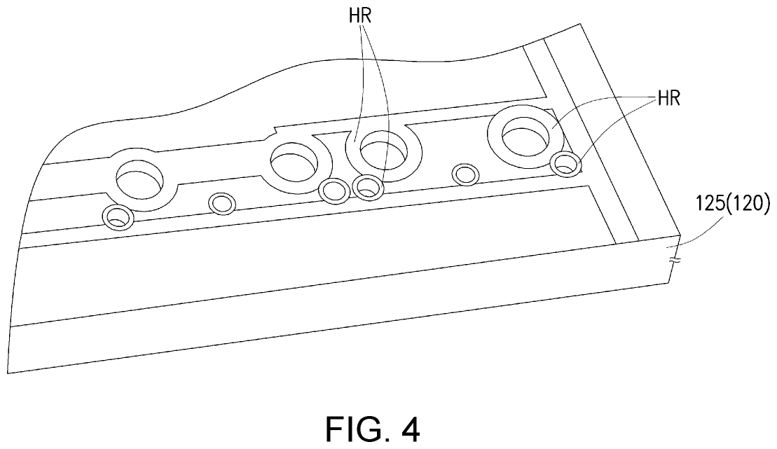

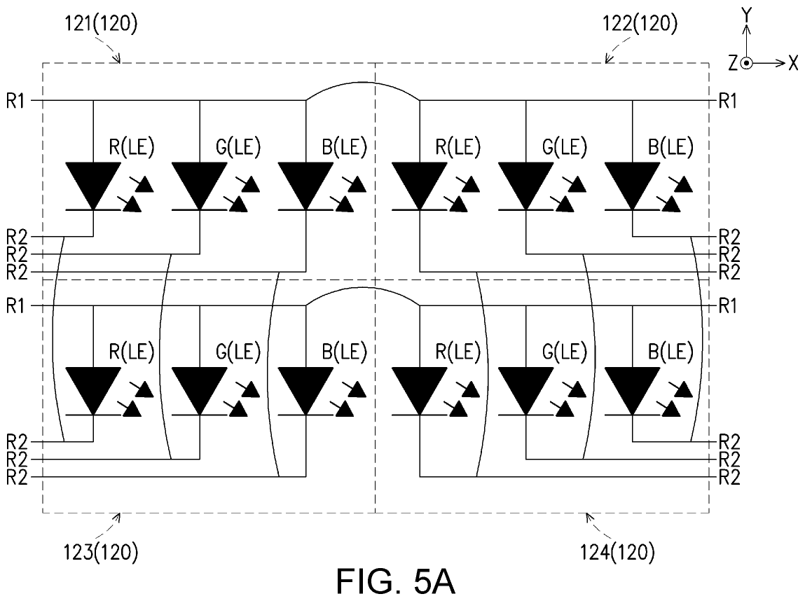

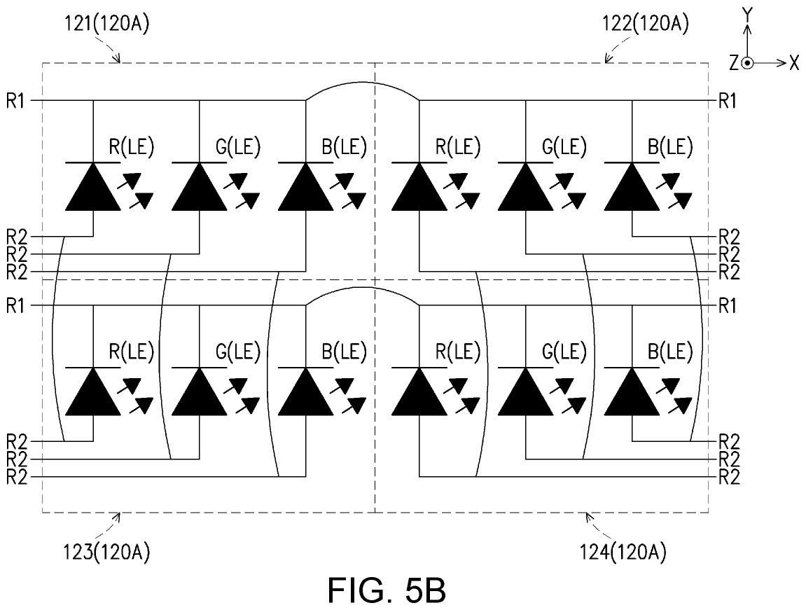

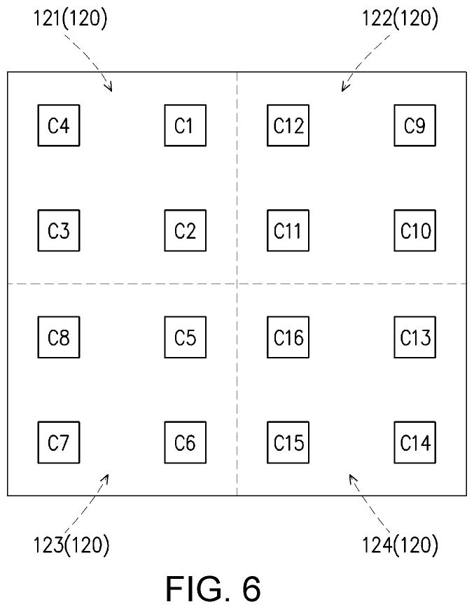

FIG. 1 is a schematic top view of a light emitting module of a display device of an embodiment according to the disclosure. FIG. 2 is a schematic view of a driving chip and a driving substrate of the display device in FIG. 1. FIG. 3 is a partially enlarged schematic view of the light emitting module of the display device in FIG. 1. FIG. 4 is a perspective schematic view of a multi-layer board of the light emitting module of the display device in FIG. 1. FIG. 5A is a circuit schematic view of the light emitting module in the display device in FIG. 1. FIG. 5B is a circuit schematic view of a light emitting module in a display device of another embodiment of the disclosure. FIG. 6 is a schematic bottom view of the light emitting module of the display device in FIG. 1.

It should be noted that for clear description of a structure of a display device 100, FIG. 1 schematically illustrates four light emitting modules 120 of the display device 100 and omits a part of components. In addition, for clear description of a structure of the light emitting module 120, FIG. 3 and FIG. 4 schematically illustrate one of the light emitting modules 120 and a multi-layer board 125 of the display device 100 and omit a part of components, respectively.

With reference to FIG. 1 and FIG. 2, in this embodiment, the display device 100 includes a driving substrate 110 and a plurality of light emitting modules 120. The light emitting modules 120 are disposed on the driving substrate 110 and are electrically connected to the driving substrate 110. Here, the driving substrate 110 is, for example but not limited to, a printed circuit board.

In detail, with reference to FIG. 3 and FIG. 4 together, in this embodiment, the light emitting module 120 includes multiple light emitting units (i.e., a first light emitting unit 121, a second light emitting unit 122, a third light emitting unit 123, and a fourth light emitting unit 124) and the multi-layer board 125. Each light emitting unit includes multiple light emitting elements LE and multiple side connectors SC. Each light emitting element LE includes a first end R1 and a second end R2. The light emitting unit is disposed on the multi-layer board 125, and the first end R1 and the second end R2 of the light emitting elements LE are connected to the side connectors SC through multiple through holes HR of the multi-layer board 125. Here, the through hole HR of the multi-layer board 125 may be a plating through hole (PTH) or a non plating through hole (NPTH), but it is not limited thereto.

Furthermore, with reference to FIG. 1 and FIG. 3 together, in this embodiment, each light emitting module 120 has sixteen side connectors SC, and each of the first light emitting unit 121, the second light emitting unit 122, the third light emitting unit 123, and the fourth light emitting unit 124 corresponds to four side connectors SC, respectively. The adjacent light emitting modules 120 may be spliced together by conducting the side connectors SC to each other. For example, FIG. 1 includes four light emitting modules 120 at top left, bottom left, top right, and bottom right. The light emitting module 120 at top left of FIG. 1 is connected, through one side connector SC of the second light emitting unit 122 and one side connector SC of the fourth light emitting unit 124 (i.e., two side connectors SC on the right side at top left), to one side connector SC of the first light emitting unit 121 and one side connector SC of the third light emitting unit 123 of the light emitting module 120 at top right (i.e., two side connectors SC on the left side at top right). The light emitting module 120 at top left of FIG. 1 may also be connected, through three side connectors SC of the third light emitting unit 123 and three side connectors SC of the fourth light emitting unit 124 (i.e., six side connectors SC on the lower side at top left), to three side connectors SC of the first light emitting unit 121 and three side connectors SC of the second light emitting unit 122 of the light emitting module 120 at bottom left (i.e., six side connectors SC on the upper side at bottom left). It should be noted that although one side connector SC and three side connectors SC are respectively disposed on each pair of two adjacent sides of each light emitting unit, this embodiment does not limit the alignment method and shape of the side connector SC, which may be determined according to requirements.

With continued reference to FIG. 1 and FIG. 3, in this embodiment, in each light emitting module 120, a surface of the side connector SC of the first light emitting unit 121, the second light emitting unit 122, the third light emitting unit 123, and the fourth light emitting unit 124 further includes a magnetic piece 126. For example, the magnetic piece 126 of one side connector SC on the right side of the second light emitting unit 122 of the light emitting module 120 at top left of FIG. 1 is made of an iron magnetic material, and the corresponding magnetic component 126 of one side connector SC on the left side of the first light emitting unit 121 of the light emitting module 120 at top right of FIG. 1 is made of a paramagnetic material; therefore, the two corresponding side connectors SC may attract each other by magnetic force. Here, the iron magnetic material is, for example but not limited to, iron, steel, nickel, cobalt, aluminum nickel, cobalt alloy, or the like, and the paramagnetic material is, for example but not limited to, platinum, tin, aluminum, or the like. In another embodiment, the magnetic piece 126 of one side connector SC on the right side of the second light emitting unit 122 of the light emitting module 120 at top left of FIG. 1 and the corresponding magnetic component 126 of one side connector SC on the left side of the first light emitting unit 121 of the light emitting module 120 at top right of FIG. 1 are made of, for example, the iron magnetic material, and the two magnetic pieces 126 have different polarities; therefore, the two corresponding side connectors SC may attract each other by magnetic force and may be electrically connected to each other. However, the disclosure is not limited thereto.

In other embodiments, the display device 100 further includes a fixed plate (not illustrated). The fixed plate has a concave trench in which multiple light emitting modules 120 are disposed, and there is a groove between the adjacent concave trenches for the side connector SC of the light emitting unit to correspond to the groove. After the light emitting module 120 is disposed in the concave trench of the fixed board, a solder such as solder paste, copper paste, or the like may be filled into the groove and be melted so that the light emitting modules 120 are spliced together by conducting the side connectors SC of the light emitting units to each other with the solder, which is still within the scope of the disclosure. In short, the method for communicating the side connectors SC of the light emitting units with each other of this embodiment includes, but not limited to, conducting the side connectors SC by magnetic attraction or with the solder.

With reference to FIG. 3 and FIG. 5A together, in this embodiment, among the light emitting units, the first end R1 of the light emitting element LE of the first light emitting unit 121 and the first end R1 of the light emitting element LE of the second light emitting unit 122 are electrically connected to each other. Among the light emitting units, the first end R1 of the light emitting element LE of the third light emitting unit 123 and the first end R1 of the light emitting element LE of the fourth light emitting unit 124 are electrically connected to each other. The second end R2 of one of the light emitting elements LE of the first light emitting unit 121 and the second end R2 of one of the light emitting elements LE of the corresponding third light emitting unit 123 are electrically connected to each other. The second end R2 of one of the light emitting elements LE of the second light emitting unit 122 and the second end R2 of one of the light emitting elements LE of the corresponding fourth light emitting unit 124 are electrically connected to each other.

In detail, in this embodiment, the first light emitting unit 121 includes three light emitting elements LE, and the three light emitting elements LE are respectively a red light emitting diode R, a green light emitting diode G, and a blue light emitting diode B that emit different colors of light. Each light emitting element LE includes the first end R1 and the second end R2, and the first ends R1 of each light emitting element LE are electrically connected in parallel. That is, the first end R1 of the red light emitting diode R, the first end R1 of the green light emitting diode G, and the first end R1 of the blue light emitting diode B are electrically connected in parallel. Similarly, the second light emitting unit 122, the third light emitting unit 123, and the fourth light emitting unit 124 respectively include three light emitting elements LE, and the three light emitting elements LE are the red light emitting diode R, the green light emitting diode G, and the blue light emitting diode B that emit different colors of light. Each light emitting element LE includes the first end R1 and the second end R2, and the first ends R1 of each light emitting element LE are electrically connected in parallel. It should be noted that the first light emitting unit 121, the second light emitting unit 122, the third light emitting unit 123, and the fourth light emitting unit 124 here are specifically encapsulated structures, where each light emitting element LE in each light emitting unit is electrically connected to the multi-layer board 125 by, for example, wire bonding.

Furthermore, in this embodiment, the first end R1 of each light emitting element LE of the first light emitting unit 121 and the first end R1 of each light emitting element LE of the second light emitting unit 122 are electrically connected in parallel. The first end R1 of each light emitting element LE of the third light emitting unit 123 and the first end R1 of each light emitting element LE of the fourth light emitting unit 124 are electrically connected in parallel. In the first light emitting unit 121 and the third light emitting unit 123, the second ends R2 of the light emitting elements LE emitting light of a same color are electrically connected in parallel. In the second light emitting unit 122 and the fourth light emitting unit 124, the second ends R2 of the light emitting element LE emitting light of a same color are electrically connected in parallel. That is, as shown in FIG. 5A, the second end R2 of the red light emitting diode R, the second end R2 of the green light emitting diode G, and the second end R2 of the blue light emitting diode B of the first light emitting unit 121 are electrically connected in parallel to the second end R2 of the red light emitting diode R, the second end R2 of the green light emitting diode G, and the second end R2 of the blue light emitting diode B of the third light emitting unit 123, respectively. The second end R2 of the red light emitting diode R, the second end R2 of the green light emitting diode G, and the second end R2 of the blue light emitting diode B in the second light emitting unit 122 are electrically connected in parallel to the second end R2 of the red light emitting diode R, the second end R2 of the green light emitting diode G, and the second end R2 of the blue light emitting diode B of the fourth light emitting unit 124, respectively.

Here, as shown in FIG. 5A, the first light emitting unit 121 and the second light emitting unit 122 are adjacently disposed (parallel to an X axial direction), and a direction of arranging the first light emitting unit 121 and the third light emitting unit 123 is parallel to a direction of arranging the second light emitting unit 122 and the fourth light emitting unit 124 (parallel to a Y axial direction). The first end R1 of each light emitting element LE is specifically a P-type electrode, and the second end R2 of each light emitting element LE is specifically an N-type electrode. In other words, the light emitting module 120 shown in FIG. 5A of this embodiment is specifically designed to be a common anode circuit. In another embodiment, with reference to FIG. 5B, the first end R1 of each light emitting element LE is specifically an N-type electrode, and the second end R2 of each light emitting element LE is specifically a P-type electrode. In other words, the light emitting module 120A is specifically designed to be a common cathode circuit, which is still within the scope of the disclosure.

Furthermore, with reference to FIG. 1 and FIG. 3, in each light emitting unit, a common pole of the first ends R1 of each light emitting element LE and the second ends R2 of each light emitting element LE are electrically connected in parallel to one of the side connectors SC, respectively. For example, as shown in FIG. 3, the common pole of the first end R1 of the red light emitting diode R, the first end R1 of the green light emitting diode G, and the first end R1 of the blue light emitting diode B of the first light emitting unit 121 is electrically connected in parallel to the side connector SC on the left side of the first light emitting unit 121, and the second end R2 of the red light emitting diode R2, the second end R2 of the green light emitting diode G, and the second end R2 of the blue light emitting diode B are electrically connected in parallel to the other three side connectors SC on the top side of the first light emitting unit 121, respectively. Similarly, the common poles of the first ends R1 of the red light emitting diodes R, the first ends R1 of the green light emitting diodes G, and the first ends R1 of the blue light emitting diodes B as well as the second ends R2 of the red light emitting diodes R, the second ends R2 of the green light emitting diodes G, and the second ends R2 of the blue light emitting diodes B of the second light emitting unit 122, the third light emitting unit 123, and the fourth light emitting unit 124 are all electrically connected to the side connectors SC in the same method. Here, it should be noted that, as shown in FIG. 1, the adjacent light emitting modules 120 are conducted to each other through the side connectors SC, and the two corresponding side connectors SC are electrically connected in parallel to one of the common pole the first end R1 of the red light emitting diode R, the first end R1 of the green light emitting diode G, and the first end R1 of the blue light emitting diode B, the second end R2 of the red light emitting diode R, and the second end R2 of the green light emitting diode G, and the second end R2 of the blue light emitting diode B. For example, the side connectors SC on the left side of the light emitting module 120 at top right of FIG. 1 and the corresponding side connectors SC on the right side of the light emitting module 120 at top left of FIG. 1 are electrically connected in parallel to the common pole of the first end R1 of the red light emitting diode R, the first end R1 of the green light emitting diode G, and the first end R1 of the blue light emitting diode B of the corresponding light emitting unit, respectively.

Furthermore, with reference to FIG. 2 and FIG. 6 together, in this embodiment, the display device 100 further includes a driving chip 130, and the driving chip 130 includes a first pin 131, a second pin 132, three third pins 133a, 133b, and 133c, and three fourth pins 134a, 134b, and 134c. The driving substrate 110 of this embodiment includes multiple pads P1, P2, P3, P4, P5, P6, P7, P8, P9, P10, P11, P12, P13, P14, P15, and P16. Each of the first light emitting unit 121, the second light emitting unit 122, the third light emitting unit 123, and the fourth light emitting unit 124 corresponds to four pads in the pads P1, P2, P3, P4, P5, P6, P7, P8, P9, P10, P11, P12, P13, P14, P15, and P16, respectively. For example, the first light emitting unit 121 corresponds to the pads P1, P2, P3, and P4, the second light emitting unit 122 corresponds to the pads P9, P10, P11, and P12, the third light emitting unit 123 corresponds to the pads P5, P6, P7, and P8, and the fourth light emitting unit 124 corresponds to the pads P13, P14, P15, and P16.

In this embodiment, the driving chip 130 is electrically connected to the pads P1, P2, P3, P4, P5, P6, P7, P8, P9, P10, P11, P12, P13, P14, P15, and P16 of the driving substrate 110. The first pin 131 of the driving chip 130 is electrically connected to the pads P1 and P9 of the driving substrate 110, and the second pin 132 of the driving chip 130 is electrically connected to the pads P5 and P13 of the driving substrate 110. The third pin 133a of the driving chip 130 is electrically connected to the pads P2 and P6 of the driving substrate 110, the third pin 133b is electrically connected to the pads P3 and P7 of the driving substrate 110, and the third pin 133c is electrically connected to the pad P4 and P8 of the driving substrate 110. The fourth pin 134a of the driving chip 130 is electrically connected to the pads P10 and P14 of the driving substrate 110, the fourth pin 134b is electrically connected to the pads P11 and P15 of the driving substrate 110, and the fourth pin 134c is electrically connected to the pad P12 and P16 of the driving substrate 110. In other words, each pin of the driving chip 130 may be divided into two paths electrically connected to two pads.

Furthermore, as shown in FIG. 2, FIG. 3, and FIG. 6, the light emitting module 120 of this embodiment further includes multiple connection pads C1, C2, C3, C4, C5, C6, C7, C8, C9, C10, C11, C12, C13, C14, C15, and C16, which respectively correspond to the pads P1, P2, P3, P4, P5, P6, P7, P8, P9, P10, P11, P12, P13, P14, P15, and P16 on the driving substrate 110, and the light emitting module 120 may be electrically connected to the driving substrate 110 by surface mount technology (SMT). The first light emitting unit 121 has the connection pads C1, C2, C3, and C4, the second light emitting unit 122 has the connection pads C9, C10, C11, and C12, the third light emitting unit 123 has the connection pads C5, C6, C7, and C8, and the fourth light emitting unit 124 has the connection pads C13, C14, C15, and C16.

The first ends R1 of the three light emitting elements LE of the first light emitting unit 121 and the first ends R1 of the three light emitting elements LE of the second light emitting unit 122 are electrically connected to the first pin 131 of the driving chip 130 through the connection pads C1 and C9 and the pads P1 and P9. The first ends R1 of the three light emitting elements LE of the third light emitting unit 123 and the first ends R1 of the three light emitting elements LE of the fourth light emitting unit 124 are electrically connected to the second pin 132 of the driving chip 130 through the connection pads C5 and C13 and the pads P5 and P13. In the first light emitting unit 121 and the third light emitting unit 123, the second ends R2 of the light emitting elements LE emitting light of the same color are electrically connected to the third pins 133a, 133b, and 133c of the driving chip 130. For example, in the first light emitting unit 121 and the third light emitting unit 123, the second ends R2 of the red light emitting diodes R emitting red light are electrically connected to the third pin 133a of the driving chip 130 through the connection pads C2 and C6 and the pads P2 and P6, respectively. Similarly, in the first light emitting unit 121 and the third light emitting unit 123, the second ends R2 of the green light emitting diodes G emitting green light are electrically connected to the third pin 133b of the driving chip 130 through the connection pads C3 and C7 and the pads P3 and P7, respectively. In the first light emitting unit 121 and the third light emitting unit 123, the second ends R2 of the blue light emitting diodes B emitting blue light are electrically connected to the third pin 133c of the driving chip 130 through the connection pads C4 and C8 and the pads P4 and P8, respectively.

In the second light emitting unit 122 and the fourth light emitting unit 124, the second ends R2 of the light emitting elements LE emitting light of the same color are electrically connected to the fourth pins 134a, 134b, and 134c of the driving chip 130. For example, in the second light emitting unit 122 and the fourth light emitting unit 124, the second ends R2 of the red light emitting diodes R emitting red light are electrically connected to the fourth pin 134a of the driving chip 130 through the connection pads C10 and C14 and the pads P10 and P14, respectively. Similarly, in the second light emitting unit 122 and the fourth light emitting unit 124, the second ends R2 of the green light emitting diodes G emitting green light are electrically connected to the fourth pin 134b of the driving chip 130 through the connection pads C11 and C15 and the pads P11 and P15, respectively. In the second light emitting unit 122 and the fourth light emitting unit 124, the second ends R2 of the blue light emitting diodes B emitting blue light are electrically connected to the fourth pin 134c of the driving chip 130 through the connection pads C12 and C16 and the pads P12 and P16, respectively.

With the design of the light emitting module 120 described above, when one of the light emitting elements LE of the light emitting units is damaged, the light emitting unit may still emit light normally. For example, when an electrical connection interface between the connection pad C2 of the red light emitting diode R of the first light emitting unit 121 and the corresponding pad P2 of the driving substrate 110 is damaged, the second end R2 of the red light emitting diode R of the third light emitting unit 123 has a trace to be electrically connected to the second end R2 of the red light emitting diode R of the first light emitting unit 121. Therefore, the red light emitting diode R of the first light emitting unit 121 still emits light. When an electrical connection interface between the connection pad C1 of the common pole of the first light emitting unit 121 and the corresponding pad P1 of the driving substrate 110 is damaged, the common pole of the first end R1 of the red light emitting diode R, the first end R1 of the green light emitting diode G, and the first end R1 of the blue light emitting diode B of the second light emitting unit 122 has a trace to be electrically connected to the common pole of the first end R1 of the red light emitting diode R, the first end R1 of the green light emitting diode G, and the first end R1 of the blue light emitting diode B of the first light emitting unit 121. Therefore, the red light emitting diode R, the green light emitting diode G, and the blue light emitting diode B of the first light emitting unit 121 still emit light. Based on this, even if the electrical connection interfaces between the connection pads C1, C2, C3, and C4 of the first light emitting unit 121 and the corresponding pads P1, P2, P3, and P4 are damaged, the first light emitting unit 121 still emit light.

It should be noted that, as shown in FIG. 1, FIG. 3, and FIG. 5A, in the light emitting module 120 of this embodiment, each light emitting unit has three-path parallel circuit protection. Therefore, if the driving substrate 110 and the light emitting modules 120 of the display device 100 suffer a strong impact, which damages the electrical connection interface between the connection pads and the corresponding pads of the driving substrate 110 or causes the pads of the driving substrate 110 to fall off in part of the light emitting modules 120, the light emitting modules 120 are spliced together by conducting the side connectors SC of the light emitting units to each other. This way, the light emitting module 120 continues to emit light. In addition, each light emitting module 120 may at most tolerate a damage on the interface between the connection pads of one of two groups of the light emitting units having different common poles and the corresponding pads. Here, the two groups of the light emitting units having different common poles are, for example, the first light emitting unit 121 and the third light emitting unit 123, or the second light emitting unit 122 and the fourth light emitting unit 124. In short, with the above design, when multiple light emitting units are subjected to a strong impact making some of the light emitting units unable to be electrically connected to the driving substrate 110, or when the light emitting elements LE in the light emitting units suffer a solder crack or an impact leading to a damage, the display device 100 using the light emitting modules 120 may allow the light emitting modules to continue to emit light with the adjacent light emitting units conducted to each other through the side connectors SC or with the circuit design of the light emitting module. This way, without affecting the functionality of the light emitting module 120, the protection of the light emitting module 120 is improved to reduce the pixel uncontrolled rate, effectively reduce the maintenance rate of the light emitting module 120, increase repair possibility, and effectively reduce the scrap uncontrolled rate of the display device 100.

In summary, the embodiments of the disclosure have at least one of the following effects. In the design of the light emitting module of the disclosure, the light emitting units are disposed on the multi-layer board and include multiple light emitting elements and multiple side connectors. The first end and the second end of the light emitting element are connected to the side connectors through the through holes of the multi-layer board. The first ends of the light emitting elements of the first light emitting unit and the second light emitting unit among the light emitting units are electrically connected to each other, and the first ends of the light emitting elements of the third light emitting unit and the fourth light emitting unit among the light emitting units are electrically connected to each other. In this way, the light emitting module of the disclosure has three-path parallel circuit design, which may improve the repair possibility of the light emitting module of the disclosure. In addition, the display device using the light emitting module of the disclosure may allow the adjacent light emitting units to be conducted to each other through the side connectors. Therefore, when multiple light emitting units in the display device are subjected to a strong impact making some of the light emitting units unable to be electrically connected to the driving substrate, the repair possibility may be increased and the scrap uncontrolled rate of the display device may be reduced.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light emitting module, comprising a plurality of light emitting units and a multi-layer board, wherein
each of the plurality of light emitting units comprises a plurality of light emitting elements and a plurality of side connectors, and each of the plurality of light emitting elements comprises a first end and a second end; and
the plurality of light emitting units are disposed on the multi-layer board, and the first end and the second end of each of the plurality of light emitting elements are connected to the plurality of side connectors through a plurality of through holes of the multi-layer board, wherein the first end of each of the plurality of light emitting elements of a first light emitting unit and a second light emitting unit among the plurality of light emitting units is electrically connected to each other, and the first end of each of the plurality of light emitting elements of a third light emitting unit and a fourth light emitting unit among the plurality of light emitting units is electrically connected to each other.

2. The light emitting module according to claim 1, wherein the plurality of side connectors are made of a magnetic material.

3. The light emitting module according to claim 1, wherein the first end is a P-type electrode, and the second end is an N-type electrode.

4. The light emitting module according to claim 1, wherein the first end is an N-type electrode, and the second end is a P-type electrode.

5. The light emitting module according to claim 1, wherein each of the plurality of light emitting elements comprises a red light emitting diode, a blue light emitting diode, and a green light emitting diode.

6. The light emitting module according to claim 1, wherein the first light emitting unit and the second light emitting unit are disposed adjacently, and a direction of arranging the first light emitting unit and the third light emitting unit is parallel to a direction of arranging the second light emitting unit and the fourth light emitting unit.

7. A display device, comprising a driving substrate and a plurality of light emitting modules, wherein
the plurality of light emitting modules are disposed on the driving substrate and are electrically connected to the driving substrate, and each of the plurality of light emitting modules comprises a plurality of light emitting units and a multi-layer board, wherein
each of the plurality of light emitting units comprises a plurality of light emitting elements and a plurality of side connectors, and each of the plurality of light emitting elements comprises a first end and a second end; and
the plurality of light emitting units are disposed on the multi-layer board, and the first end and the second end of each of the plurality of light emitting elements are connected to the plurality of side connectors through a plurality of through holes of the multi-layer board, wherein the first end of each of the plurality of light emitting elements of a first light emitting unit and a second light emitting unit among the plurality of light emitting units is electrically connected to each other, the first end of each of the plurality of light emitting elements of a third light emitting unit and a fourth light emitting unit among the plurality of light emitting units is electrically connected to each other, and the plurality of light emitting units that are adjacent are conducted to each other through the plurality of side connectors.

8. The display device according to claim 7, further comprising:
a driving chip, comprising a first pin, a second pin, a plurality of third pins, and a plurality of fourth pins, wherein
the first end of each of the plurality of light emitting elements of the first light emitting unit and the first end of each of the plurality of light emitting elements of the second light emitting unit are electrically connected to the first pin of the driving chip;
the first end of each of the plurality of light emitting elements of the third light emitting unit and the first end of each of the plurality of light emitting elements of the fourth light emitting unit are electrically connected to the second pin of the driving chip;
in the first light emitting unit and the third light emitting unit, the second end of each of the plurality of light emitting elements emitting light of a same color is electrically connected to each of the plurality of third pins of the driving chip; and
in the second light emitting unit and the fourth light emitting unit, the second end of each of the plurality of light emitting elements emitting light of a same color is electrically connected to each of the plurality of fourth pins of the driving chip.

9. The display device according to claim 7, wherein the driving substrate comprises a plurality of pads, and each of the first light emitting unit, the second light emitting unit, the third light emitting unit, and the fourth light emitting unit corresponds to four of the plurality of pads, respectively.

10. The display device according to claim 7, wherein the first end is a P-type electrode, and the second end is an N-type electrode.

11. The display device according to claim 7, wherein the first end is an N-type electrode, and the second end is a P-type electrode.

12. The display device according to claim 7, wherein each of the plurality of light emitting elements comprises a red light emitting diode, a blue light emitting diode, and a green light emitting diode.

13. The display device according to claim 7, wherein the first light emitting unit and the second light emitting unit are disposed adjacently, and a direction of arranging the first light emitting unit and the third light emitting unit is parallel to a direction of arranging the second light emitting unit and the fourth light emitting unit.

14. The display device according to claim 7, wherein the plurality of light emitting modules are spliced together by conducting the plurality of side connectors of each of the plurality of light emitting units to each other with a solder.

15. The display device according to claim 7, wherein the plurality of light emitting modules are spliced together by conducting the plurality of side connectors of each of the plurality of light emitting units to each other by magnetic attraction.

16. The display device according to claim 7, wherein the driving substrate comprises a printed circuit board.
